(19) United States
(12) Patent Application Publication
(10) Pub. No.: US 2014/0072818 A1
(43) Pub. Date: Mar. 13, 2014

(54) EPOXY RESIN COMPOSITION, AND PREPREG AND COPPER CLAD LAMINATE MADE THEREFROM

(71) Applicant: GUANGDONG SHENGYI SCI.TECH CO., LTD, Dongguan City (CN)

(72) Inventors: Xian-Ping ZENG, Dongguan City (CN); Na-Na REN, Dongguan City (CN); Biao ZHOU, Dongguan City (CN)

(73) Assignee: GUANGDONG SHENGYI SCI.TECH CO., LTD, Dongguan City (CN)

(21) Appl. No.: 13/831,854

(22) Filed: Mar. 15, 2013

(30) Foreign Application Priority Data
Sep. 7, 2012 (CN) 201210330407.1

(51) Int. Cl. H05K 1/03

(52) U.S. Cl. CPC H05K 1/0373
USPC 428/457; 523/451

(57) ABSTRACT

The present invention relates to an epoxy resin composition, and a prepreg and a copper clad laminate made therefrom. The epoxy resin composition comprises: (A) epoxy resin containing two or over two epoxy groups, (B) active ester curing agent, and (C) phosphate salt compound. The epoxy resin composition of the present invention adopts epoxy resin with specific molecular structure, which has comparatively high functionality, so the cured products have high glass transition temperature and low hydroscopic property; active ester is adopted as the curing agent to make full use of the advantages that polar groups will not be produced when the active ester reacts with the epoxy resin; the prepreg and copper clad laminate made therefrom of the present invention can achieve halogen-free flame retardance, and meanwhile have excellent dielectric properties and good resistance to humidity and heat.

### RELATED APPLICATION

This application claims priority to Chinese Application Serial Number 201210330407.1, filed Sep. 7, 2012, which is herein incorporated by reference.

### FIELD OF THE INVENTION

The present invention relates to an epoxy resin composition, particularly relates to an epoxy resin composition, and a prepreg and a copper clad laminate made therefrom,

### BACKGROUND OF THE INVENTION

With the development of high speed, multifunctional information processing of electronic products, the applied frequency becomes higher and higher, and an applied frequency of 3-6 GHz will become mainstream, so, besides higher requirement to the heat resistance of a laminate material, the dielectric constant and dielectric loss value thereof are required to be lower and lower. Existing conventional FR-4 materials are hard to meet the development requirement of high frequency, high speed electronic products, and at the same time, substrate materials will not only play the traditional role as a mechanical support, but, together with electronic components, will be an important way for producers and designers of PCBs and terminals to improve the product performance. High DK will make the signal transmission rate slow, and high Df will make part of the signal be converted into heat energy that will be wasted in the substrate materials, so, decreasing DK/Df has become a focus for the field of substrates. Conventional FR-4 materials generally adopt dicyandiamide as the curing agent that has good processability for the tertiary amine thereof, but because the C—N bond thereof is comparatively weak to be easily cracked at high temperature, the thermal decomposition temperature of the cured products is comparatively low to be hard to meet the heat resistance requirement of lead-free technology. In such a background, with lead-free technology being widely carried out since the year 2006, phenolic resin are adopted as the curing agent for epoxy resin. Phenolic resin has high density of benzene ring heat resistance structure, so the heat resistance of the resin system of cured phenolic resin and epoxy resin has excellent heat resistance, but, the trend that the dielectric properties of the cured products get deteriorated appears at the same time.

Japanese patent publication No. 2002-012650, and Japanese patent publication No. 2003-082063 disclose a series of active ester curing agents containing benzene ring, naphthalene ring or biphenyl structure as the curing agent for epoxy resin, such as IAAN, IABN, TriABN, and TAAN, comparing with conventional phenolic resin, which can obviously decrease the dielectric constant and dielectric loss value of the cured products.

Japanese patent publication No. 2003-252958 discloses that the dielectric constant and dielectric loss value of the cured products can be decreased by adopting biphenyl type epoxy resin and active ester as the curing agent, but, because the adopted epoxy resin is bifunctional and the cross-linking density of the active ester is low, the cured products have comparatively low heat resistance and glass transition temperature.

Japanese patent publication No. 2004-155990 discloses a multifunctional active ester curing agent obtained by aromatic carboxylic acid reacting with aromatic phenol, and cured products with comparatively high heat resistance, good dielectric constant and good dielectric loss value can be obtained by using the multifunctional active ester curing agent to cure novolac type epoxy resin.

Japanese patent publication No. 2009-235165 discloses a new multifunctional active ester curing agent, which can obtain cured products with comparatively high glass transition temperature, comparatively low dielectric constant and dielectric loss value by curing an epoxy resin containing aliphatic structure.

Japanese patent publication No. 2009-040919 discloses a thermosetting resin composition with stable dielectric constant and excellent adherence to conducting layer, which mainly comprises an epoxy resin, an active ester hardener, a hardening accelerator, and an organic solvent. Wherein, the obtained cured products have good adherence to copper foils, dielectric constant and dielectric loss value; the usage amount of the epoxy resin and active ester was studied, but the relationship of the structure and property of the epoxy resin and active ester was not studied.

In addition, Japanese patent publication No. 2009-242559, Japanese patent publication No. 2009-242560, Japanese patent publication No. 2010-977344, and Japanese patent publication No, 2010-077343 respectively disclose that cured products with low hydroscopic property, low dielectric constant and dielectric loss tangent can be obtained from alkylated phenol novolac type epoxy resin, alkylated naphthol novolac type epoxy resin, and biphenyl type novolac epoxy resin by using an active ester as the curing agent,

The above existing patent technologies all disclose that active esters are used as the curing agent for epoxy resins to improve moisture resistance, decrease hydroscopic property, and decrease dielectric constant and dielectric loss value of the cured products, but the disadvantages are that it is hard to achieve good equilibrium between heat resistance and dielectric properties, which is achieved to make that the cured products could simultaneously have high glass transition temperature and low dielectric loss tangent, have comparatively stable dielectric properties under frequency variation, and have lower hydroscopic property. Meanwhile, how to achieve halogen-free flame retardance of the cured products is not studied.

### SUMMARY OF THE INVENTION

An object of the present invention is to provide an epoxy resin composition, which can provide good dielectric properties, humidity resistance and heat resistance required by a copper clad laminate, and achieve halogen-free flame retardance.

Another object of the present invention is to provide a prepreg and a copper clad laminate made from the above mentioned epoxy resin composition, which have good dielectric properties, humidity resistance and heat resistance, also have high glass transition temperature and comparatively low hydroscopic property, and can achieve halogen-free flame retardance.

To achieve the above objects, the present invention provides an epoxy resin composition, which comprises:

(A) epoxy resin containing two or over two epoxy groups, B active ester curing agent, and (C) phosphate salt compound;

the structure formula of the component (A) epoxy resin containing two or over two epoxy groups is shown as follows:

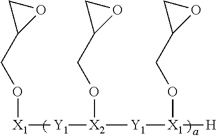

wherein, X₁ and X₂ are identical or different, which represent

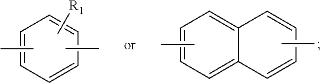

Y₁ represents —CH₂—,

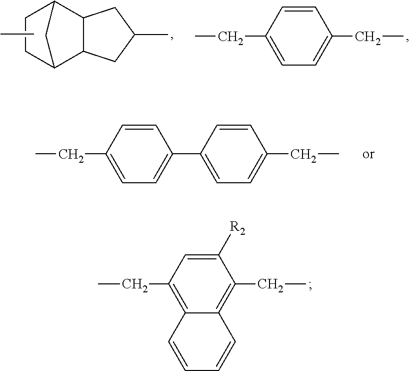

wherein, R₁ represents hydrogen atom, or alkyl with the number of carbon atoms being 1-10, and, R₂ represents hydrogen atom, or alkyl with the number of carbon atoms being 1-10: a represents an integer of 1-30,

Taking the usage amount of the component (A) epoxy resin containing two or over two epoxy groups as 100 parts by weight, the usage amount of the component (B) active ester curing agent is calculated according to the equivalent ratio of epoxy equivalent weight to active ester equivalent weight, and the equivalent ratio is 0.85-1.2.

Taking the total amount of the component (A), the component (B) and the component (C) as 100 parts by weight, the usage amount of the component (C) phosphate salt compound is 5-20 parts by weight.

The component (B) active ester curing agent is obtained from the reaction of a phenol compound containing aliphatic hydrocarbon structure as connection structure, together with bifunctional carboxylic acid aromatic compound or acid halide, and a monohydroxy compound.

The usage amount of the bifunctional carboxylic acid aromatic compound or acid halide is 1 mol, the usage amount of the phenol compound containing aliphatic hydrocarbon structure as connection structure is 0.05-0.75 mol, and the usage amount of the monohydroxy compound is 0.25-0.95 mol.

The structure formula of the component (B) active ester curing agent is shown as follows:

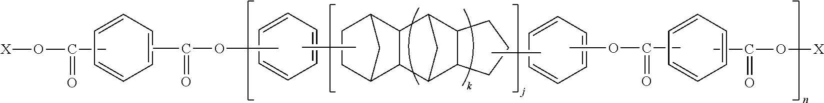

wherein, X represents benzene ring or naphthalene ring, j represents 0 or 1, k represents 0 or 1, and n ranges from 0.25 to 2.5.

The structure formula of the component (C) phosphate salt compound is shown as follows.

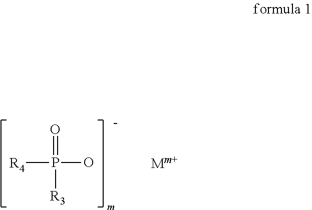

wherein, m represents 2 or 3; R₃ and R₄ represent alkyl with the number of carbon atoms being 1-6, or aryl; M represents metal atom that is one selected from calcium, magnesium, aluminum, arsenic, zinc, and iron.

The epoxy resin composition of the present invention also comprises curing accelerator, and the curing accelerator is one or a mixture of more selected from the group consisting of imidazole compounds, derivatives of imidazole compounds, piperidine compounds, Lewis acids, and triphenyl phosphine.

The epoxy resin composition of the present invention also comprises filler, which is organic filler or inorganic filler; taking the total amount of the component (A), the component (B) and the component (C) as 100 parts by weight, the usage amount of the filler is 5-500 parts by weight.

The inorganic filler is one or more selected from the group consisting of is natural silica, fused silica, spherical silica, hollow silica, glass powder, aluminum nitride, boron nitride, silicon carbide, aluminum hydroxide, titanium dioxide, strontium titanate, barium titanate, alumina, barium sulfate, talcum powder, calcium silicate, calcium carbonate, and mica; the organic filler is one or more selected from polytetrafluoroethylene powder, polyphenylene sulfide powder, and poly(ether sulfones) powder.

Meanwhile, the present invention provides a prepreg made from the above mentioned epoxy resin composition, which comprises a reinforcing material, and the epoxy resin composition that adheres to the reinforcing material after the reinforcing material is dipped in the epoxy resin composition and then is dried.

In addition, the present invention also provides a copper clad laminate made from the above mentioned prepreg, which comprises a plurality of laminated prepregs and copper foil cladded to one side or two sides of the laminated prepregs.

The advantages of the present invention: (1) the epoxy resin composition of the present invention adopts epoxy resin with specific molecular structure, which has a comparatively high functionality, so the cured products have low hydroscopic property; (2) the epoxy resin composition of the present invention adopts active ester as the curing agent to make full use of the advantages that polar groups will not be produced when the active ester reacts with the epoxy resin, thereby having excellent dielectric properties and good resistance to humidity and heat, and adopts phosphorus-containing flame retardant with specific structure to achieve halogen-free flame retardance without sacrificing heat resistance, low hydroscopic property, and excellent dielectric properties of the original cured products, of which the flame retardance can reach the level of UL94 V-0; (3) the prepreg and copper clad laminate made from the above mentioned epoxy resin composition of the present invention have excellent dielectric properties and good resistance to humidity and heat, of which the flame retardance can reach the level of UL94 V-0.

### DESCRIPTION OF THE PREFERRED EMBODIMENT

The epoxy resin composition of the present invention comprise

(A) epoxy resin containing two or over two epoxy groups, (B) active ester curing agent, and (C) phosphate salt compound;

the structure formula of the component (A) epoxy resin containing two or over two epoxy groups is shown as follows:

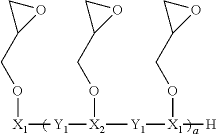

wherein, X₁ and X₂ can be identical or different, which represent

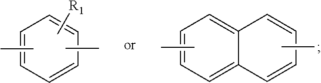

Y₁ represents —CH₂—,

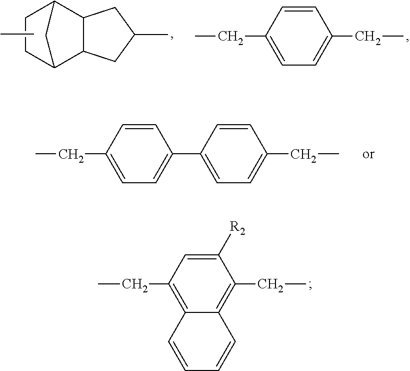

wherein, R₁ represents hydrogen atom, or alkyl with the number of carbon atoms being 1-10, and, R₂ represents hydrogen atom, or alkyl with the number of carbon atoms being 1-10; a represents an integer of 1-30.

the preferred structure formula of the component (A) epoxy resin containing two or over two epoxy groups is shown as follows:

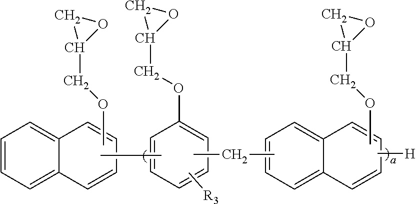

wherein, a represents an integer of 1-10, R₃ represents hydrogen atom, or alkyl with the number of carbon atoms being 1-5.

More specific structure can be as shown in the following structure formulas:

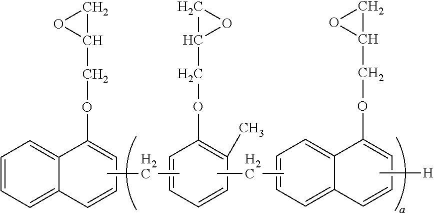

wherein, a represents an integer of 1-10;

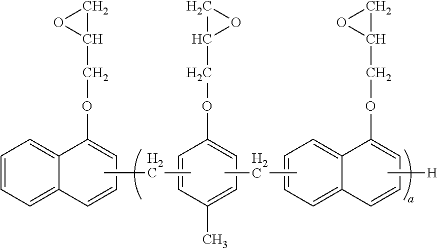

wherein, a represents an integer of 1-10.

The preferred structure formula of the component (A) epoxy resin containing two or over two epoxy groups can also the shown as follows:

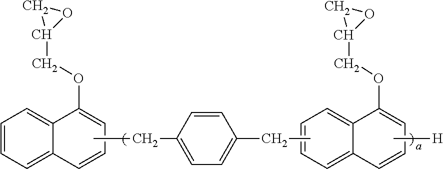

wherein, a represents an integer of 1-10;

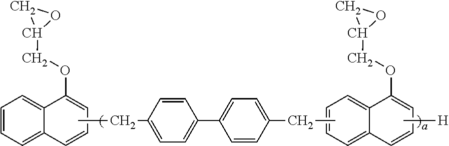

wherein, a represents an integer of 1-10;

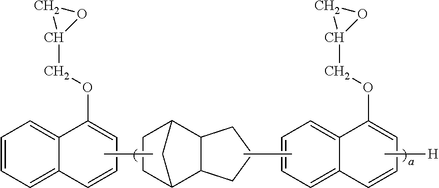

wherein, a represents an integer of 1-10;

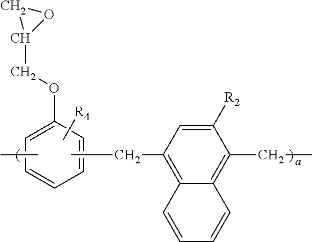

wherein, a represents an integer of 1-10; R₄ represents hydrogen atom, or alkyl with the number of carbon atoms being 1-5.

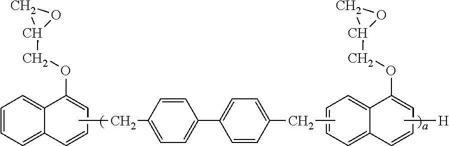

wherein, a represents an integer of 1-10.

In the epoxy resin composition of the present invention, the component (B) active ester curing agent is obtained from the reaction of a phenol compound containing aliphatic hydrocarbon structure as connection structure, together with bifunctional carboxylic acid aromatic compound or acid halide, and a monohydroxy compound. The active ester is mainly used to cure the epoxy resin, and because no secondary hydroxy is produced after the active ester and the epoxy resin are cured, the cured products substantially comprise no hydroxy polar groups, thereby having good dielectric properties, low hydroscopic property, and good resistance to humidity and heat.

The usage amount of the bifunctional carboxylic acid aromatic compound or acid halide is 1 mol, the usage amount of the phenol compound containing aliphatic hydrocarbon structure as connection structure is 0.05-0.75 mol, and the usage amount of the monohydroxy compound is 0.25-0.95 mol. The structure of the bifunctional hydroxy carboxyl can be defined as follows:

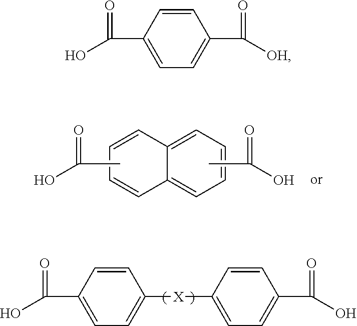

wherein, X represents alkylene with the number of carbon atoms being 1-5.

The structure of the phenol compound containing aliphatic hydrocarbon structure as connection structure can be defined as the follows:

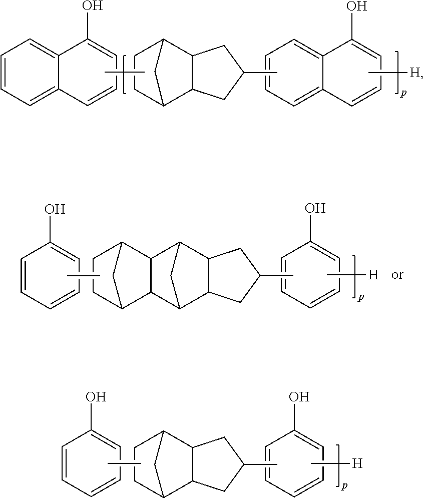

wherein, p represents an integer of 1-5.

The preferred structure formula of the component (B) active ester curing agent is shown as follows:

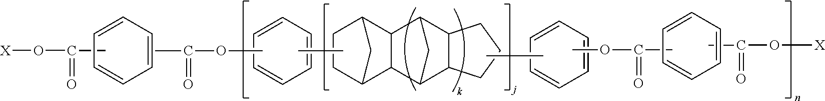

wherein, X represents benzene ring or naphthalene ring, j represents 0 or 1, k represents 0 or 1, and n ranges from 0.25 to 2.5,

Taking the usage amount of the component (A) epoxy resin containing two or over two epoxy groups as 100 parts by weight, the usage amount of the active ester curing agent is calculated according to the equivalent ratio of epoxy equivalent weight to active ester equivalent weight, thus, the equivalent ratio is 0.85-1.2, preferred to be 0.9-1.1, and more preferred to be 0.95-1.05.

In the epoxy resin composition of the present invention, the component (C) phosphate salt compound has the structure formula shown as follows:

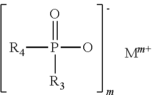

wherein, m represents 2 or 3; R₃ and R₄ represent alkyl with the number of carbon atoms being 1-6, or aryl; M represents metal atom that is one selected from calcium, magnesium, aluminum, arsenic, zinc, and iron. Considering from decreasing the hydroscopic property and increasing the phosphorus content of the epoxy resin composition, M is preferred to be aluminum or sodium, but if further considering from as far as possible decreasing the effect of the addition of the flame retardant to the dielectric properties of the cured epoxy resin composition, M is more preferred to be aluminum.

More particularly, the structure formula of the phosphate salt compound in the present invention is as follows;

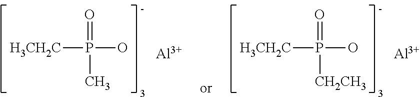

The object of the phosphate salt compound in the present invention is for to flame retardance, of which the usage amount is not particularly restrictive, so long as it can make the cured products to reach the level of UL 94 V-0, To ensure the cured products to have better overall performances, such as heat resistance and hydrolysis resistance, taking the total amount of the component (A), the component (B) and the component (C) as 100 parts by weight, the usage amount of the phosphate salt compound is 5-20 parts by weight, and further preferred to be 8-15 parts by weight.

The epoxy resin composition of the present invention can also comprise curing accelerator. The curing accelerator is not particularly restrictive, so long as it can catalyze the reaction of epoxy group and decrease the reaction temperature of the curing system, which is preferred to be one or a mixture of more selected from the group consisting of imidazole compounds, derivatives of imidazole compounds, piperidine compounds, Lewis acids, and triphenyl phosphine. The imidazole compounds can be such as 2-methylimidazole, 2-phenylimidazole, and 2-ethyl-4-methylimidazole; the piperidine compounds can be such as 2,3-diaminopiperidine, 2,5-diaminopiperidine-2,6-diaminopiperidine, 2,5-diamino-3-methylpiperidine, 2-amino-4-4methylpiperidine, 2-amino-3-nitropiperidine, 2-amino-5-nitropiperidine, and 4-dimethylaminopiperidine. Taking the total amount of the component (A), the component (B) and the component (C) as 100 parts by weight, the usage amount of the curing accelerator is 0.05-1.0 parts by weight.

The epoxy resin composition of the present invention can also comprise filler, which is organic filler or inorganic filler. The filler that can be added as required is not particularly restrictive; the inorganic filler can be one or more selected from the group consisting of natural silica, fused silica, spherical silica, hollow silica, glass powder, aluminum nitride, boron nitride, silicon carbide, aluminum hydroxide, titanium dioxide, strontium titanate, barium titanate, alumina, barium sulfate, talcum powder, calcium silicate, calcium carbonate, and mica; the organic filler can be one or more selected from polytetrafluoroethylene powder, polyphenylene sulfide, and poly(ether sulfones) powder. In addition, the shape, particle diameter, etc. of the inorganic filler is not particularly restrictive. The particle diameter generally is 0.01-50 μm, preferred to be 0.01-20 μm, and more preferred to be 0.1-10 μm; the inorganic filler in such a range of particle diameter is more easily dispersed in the resin solution. In addition, taking the total amount of the component (A), the component (B) and the component (C) as 100 parts by weight, the usage amount of the filler is not particularly restrictive, which is 5-500 parts by weight, preferred to be 5-300 parts by weight, more preferred to be 5-200 parts by weight, and most preferred to be 15-100 parts by weight.

The prepreg made from the above mentioned epoxy resin composition comprises a reinforcing material, and the epoxy resin composition that adheres to the reinforcing material after the reinforcing material is dipped in the epoxy resin composition and then is dried. The reinforcing material can use reinforcing materials of existing technology, such as fiberglass cloth.

The copper clad laminate made from the above mentioned prepreg comprises a plurality of laminated prepregs and copper foil cladded to one side or two sides of the laminated prepregs.

Prepare the epoxy resin composition of the present invention into a solution with a certain concentration, dip the reinforcing material in the solution, and then dry the reinforcing material under a certain temperature to remove the solvent and semi-cure the epoxy resin composition, thereby obtaining the prepreg. Then, overlay a plurality of the prepregs with each other in a certain sequence, respectively clad copper foils to the two sides of the prepregs overlaid with each other, and then cure the prepregs in hot press at a curing temperature of 150-250° C. and a curing pressure of 25-60 Kg/cm², thereby obtaining a copper clad laminate.

The following embodiments are merely examples to explain the present invention, and not to limit the scope of the present invention.

### Embodiment 1

Set a vessel, add 100 parts by weight of naphthol type novolac epoxy resin NC-7300L (provided by Nippon Kayaku Co., Ltd., EEW being 214 g/eq) into the vessel, then add 105 parts by weight of HPC-8000-65T provided by Japanese DIC Co., Ltd., solid content being 65%) as the active ester curing agent to stir evenly, then add 30 parts by weight of phosphate aluminum salt (provided by Clariant company, phosphorus content being 23%) as the flame retardant, then add 0.075 parts by weight of DMAP as the curing accelerator, then add methylbenzene as a solvent into the vessel, and continue to stir evenly, thereby obtaining a glue solution. Dip fiberglass cloth (type being 2116, thickness being 0.08 mm) in the above mentioned glue solution, control the fiberglass cloth to get an appropriate thickness, and then dry the fiberglass cloth by heat to remove the solvent, thereby obtaining prepregs. Overlay a plurality of the prepared prepregs with each other, respectively clad a piece of copper foil to the two sides of the prepregs overlaid with each other, and then cure the prepregs in hot press at a curing temperature of 150-250° C., a curing pressure of 25-60 Kg/cm² and a curing time of 90 minutes, thereby obtaining a copper clad laminate.

### Embodiment 2

Set a vessel, add 100 parts by weight of naphthol type novolac epoxy resin NC-7000L (provided by Nippon Kayaku Co., Ltd., EEW being 232 g/eq) into the vessel, then add 95 parts by weight of HPC-8000-65T (provided by Japanese DIC Co., Ltd., solid content being 65%/as the active ester curing agent to stir evenly, then add 30 parts by weight of phosphate aluminum salt (provided by Clariant company, phosphorus content being 23%) as the flame retardant, then add 0.075 parts by weight of DMAP as the curing accelerator, then add methylbenzene as a solvent into the vessel, and continue to stir evenly, thereby obtaining a glue solution. Dip fiberglass cloth (type being 2116, thickness being 0.08 mm) in the above mentioned glue solution, control the in fiberglass cloth to get an appropriate thickness, and then dry the fiberglass cloth by heat to remove the solvent, thereby obtaining prepregs. Overlay a plurality of the prepared prepregs with each other, respectively clad a piece of copper foil to the two sides of the prepregs overlaid with each other, and then cure the prepregs in hot press at a curing temperature of 150-250° C., a curing pressure of 25-60 Kg/cm² and a curing time of 90 minutes, thereby obtaining a copper clad laminate.

### Embodiment 3

Set a vessel, add 100 parts by weight of naphthol type novolac epoxy resin HP-5000 (provided by Japanese DIC Co., Ltd., EEW being 250 g/eq) into the vessel, then add 90 parts by weight of HPC-8000-65T provided by Japanese DIC Co., Ltd., solid content being 65%) as the active ester curing agent to stir evenly, then add 35 parts by weight of phosphate aluminum salt (provided by Clariant company, phosphorus content being 23%) as the flame retardant, then add 0.075 parts by weight of DMAP as the curing accelerator, then add methylbenzene as a solvent into the vessel, and continue to stir evenly, thereby obtaining a glue solution Dip fiberglass cloth (type being 2116, thickness being 0.08 mm) in the above mentioned glue solution, control the fiberglass cloth to get an appropriate thickness, and then dry the fiberglass cloth by heat to remove the solvent, thereby obtaining prepregs. Overlay a plurality of the prepared prepregs with each other, respectively clad a piece of copper foil to the two sides of the prepregs overlaid with each other, and then cure the prepregs in hot press at a curing temperature of 150-250° C., a curing pressure of 25-60 Kg/cm² and n g time of 90 minutes, thereby obtaining a copper clad laminate.

### Embodiment 4

Set a vessel, add 100 parts by weight of dicyclopentadiene type novolac epoxy resin HP-7200H (provided by Japanese DIC Co., Ltd., EEW being 278 g/eq) into the vessel, then add 79.6 parts by weight of HPC-8000-65T (provided by Japanese DIC Co., Ltd., solid content being 65%) as the active ester curing agent to stir evenly, then add 35 parts by weight of phosphate aluminum salt (provided by Clariant company, phosphorus content being 23%) to as the flame retardant, then add 0.075 parts by weight of DMAP as the curing accelerator, then add methylbenzene as a solvent into the vessel, and continue to stir evenly, thereby obtaining a glue solution. Dip fiberglass cloth (type being 2116, thickness being 0.08 mm) in the above mentioned glue solution, control the fiberglass cloth to get an appropriate thickness, and then dry the fiberglass cloth by heat to remove the solvent, thereby obtaining prepregs. Overlay a plurality of the prepared prepregs with each other, respectively clad a piece of copper foil to the two sides of the prepregs overlaid with each other, and then cure the prepregs in hot press at a curing temperature of 150-250° C., a curing pressure of 25-60 Kg/cm² and a curing time of 90 minutes, thereby obtaining a copper clad laminate.

### Embodiment 5

Set a vessel, add 100 parts by weight of aralkyl phenyl type novolac epoxy resin NC-2000L (provided by Nippon Kayaku Co., Ltd., EEW being 238 g/eq) into the vessel, then add 93.7 parts by weight of HPC-8000-65T (provided by Japanese DIC Co., Ltd., solid content being 65%) as the active ester curing agent to stir evenly, then add 35 parts by weight of phosphate aluminum salt (provided by Clariant company, phosphorus content being 23%) as the flame retardant, then add 0.075 parts by weight of DMAP as the curing accelerator, then add methylbenzene as a solvent into the vessel, and continue to stir evenly, thereby obtaining a glue solution. Dip fiberglass cloth (type being 2116, thickness being 0.08 mm) in the above mentioned glue solution, control the fiberglass cloth to get an appropriate thickness, and then dry the fiberglass cloth by heat to remove the solvent, thereby obtaining prepregs. Overlay a plurality of the prepared prepregs with each other, respectively clad a piece of copper foil to the two sides of the prepregs overlaid with each other, and then cure the prepregs in hot press at a curing temperature of 150-250° C., a curing pressure of 25-60 Kg/cm² and a curing time of 90 minutes, thereby obtaining a copper clad laminate.

### Embodiment 6

Set a vessel, add 100 parts by weight of biphenyl type novolac epoxy to resin NC-3000H (provided by Nippon Kayaku Co., Ltd., EEW being 288 g/eq) into the vessel, then add 77.5 parts by weight of HPC-8000-65T (provided by Japanese DIC Co., Ltd., solid content being 65%) as the active ester curing agent to stir evenly, then add 30 parts by weight of phosphate aluminum salt (provided by Clariant company, phosphorus content being 23%) as the flame retardant, then add 0.075 parts by weight of DMAP as the curing accelerator, then add methylbenzene as a solvent into the vessel, and continue to stir evenly, thereby obtaining a glue solution. Dip fiberglass cloth (type being 2116, thickness being 0.08 mm) in the above mentioned glue solution, control the fiberglass cloth to get an appropriate thickness, and then dry the fiberglass cloth by heat to remove the solvent, thereby obtaining prepregs. Overlay a plurality of the prepared prepregs with each other, respectively clad a piece of copper foil to the two sides of the prepregs overlaid with each other, and then cure the prepregs in hot press at a curing temperature of 150-250° C., a curing pressure of 25-60 Kg/cm² and a curing time of 90 minutes, thereby obtaining a copper clad laminate.

### Embodiment 7

Set a vessel, add 100 parts by weight of naphthol type novolac epoxy resin HP-6000 (provided by Japanese DIC Co., Ltd., EEW being 250 g/eq) into the vessel, then add 90 parts by weight of HPC-8000-65T (provided by Japanese DIC Co., Ltd., solid content being 65%) as the active ester curing agent to stir evenly, then add 35 parts by weight of phosphate aluminum salt (provided by Clariant company, phosphorus content being 23%) as the flame retardant, then add 0.075 parts by weight of DMAP as the curing accelerator, then add methylbenzene as a solvent into the vessel, and continue to stir evenly, thereby obtaining a glue solution. Dip fiberglass cloth (type being 2116, thickness being 0.08 mm) in the above mentioned glue solution, control the fiberglass cloth to get an appropriate thickness, and then dry the fiberglass cloth by heat to remove the solvent, thereby obtaining prepregs. Overlay a plurality of the prepared prepregs with each other, respectively clad a piece of copper foil to the two sides of the prepregs overlaid with each other, and then cure the prepregs in hot press at a curing temperature of 150-250° C., a curing pressure of 25-60 Kg/cm² and a curing time of 90 minutes, thereby obtaining a copper clad laminate.

### Embodiment 8

Set a vessel, add 100 parts by weight of naphthol type novolac epoxy resin EXA-7318 (provided by Japanese DIC Co., Ltd., EEW being 250 g/eq) into the vessel, then add 90 parts by weight of HPC-8000-65T (provided by Japanese DIC Co., Ltd., solid content being 65%) as the active ester curing agent to stir evenly, then add 35 parts by weight of phosphate aluminum salt (provided by Clariant company, phosphorus content being 23%) as the flame retardant, then add 0.075 parts by weight of DMAP as the curing accelerator, then add methylbenzene as a solvent into the vessel, and continue to stir evenly, thereby obtaining a glue solution. Dip fiberglass cloth (type being 2116, thickness being 0.08 mm) in the above mentioned glue solution, control the fiberglass cloth to get an appropriate thickness, and then dry the fiberglass cloth by heat to remove the solvent, thereby obtaining prepregs. Overlay a plurality of the prepared prepregs with each other, respectively clad a piece of copper foil to the two sides of the prepregs overlaid with each other, and then cure the prepregs in hot press at a curing temperature of 150-250° C., a curing pressure of 25-60 Kg/cm² and a curing time of 90 minutes, thereby obtaining a copper clad laminate.

### Comparison Example 1

Set a vessel, add 100 parts by weight of phenol novolac type epoxy resin N690 (provided by Japanese DIC Co., Ltd., EEW being 205 g/eq) into the vessel, then add 108.9 parts by weight of HPC-8000-65T (provided by Japanese DIC Co., Ltd., solid content being 65%) as the active ester curing agent to stir evenly, then add 30 parts by weight of phosphate aluminum salt (provided by Clariant company, phosphorus content being 23%) as the flame retardant, then add 0.075 parts by weight of DMAP as the curing accelerator, then add methylbenzene as a solvent into the vessel, and continue to stir evenly, thereby obtaining a glue solution. Dip fiberglass cloth (type being 2116, thickness being 0.08 mm) in the above mentioned glue solution, control the fiberglass cloth to get an appropriate thickness, and then dry the fiberglass cloth by heat to remove the solvent, thereby obtaining prepregs. Overlay a plurality of the prepared prepregs with each other, respectively clad a piece of copper foil to the two sides of the prepregs overlaid with each other, and then cure the prepregs in hot press at a curing temperature of 150-250° C., a curing pressure of 25-60 Kg/cm² and a curing time of 90 minutes, thereby obtaining a copper clad laminate.

### Comparison example 2

Set a vessel, add 50 parts by weight of phenol novolac type epoxy resin N690 (provided by Japanese DIC Co., Ltd., EEW being 205 g/eq) and 50 parts by weight of high-bromide epoxy resin BREN-105 (provided by Nippon Kayaku Co., Ltd., bromine content being 35%) into the vessel, then add 96.9 parts by weight of HPC-8000-65T provided by Japanese DIG Co., Ltd., solid content being 65%) as the active ester curing agent to stir evenly, then add 0.075 parts by weight of DMAP as the curing accelerator, then add methylbenzene as a solvent into the vessel, and continue to stir evenly, thereby obtaining a glue solution. Dip fiberglass cloth (type being 2116, thickness being 0.08 mm) in the above mentioned glue solution, control the fiberglass cloth to get an appropriate thickness, and then dry the fiberglass cloth by heat to remove the solvent, thereby obtaining prepregs. Overlay a plurality of the prepared prepregs with each other, respectively clad a piece of copper foil to the two sides of the prepregs overlaid with each other, and then cure the prepregs in hot press at a curing temperature of 150-250° C., a curing pressure of 25-60 Kg/cm² and a curing time of 90 minutes, thereby obtaining a copper clad laminate.

### Comparison Example 3

Set a vessel, add 100 parts by weight of biphenyl type novolac epoxy resin NC-3000H (provided by Nippon Kayaku Co., Ltd., EEW being 288 g/eq) into the vessel, then add 36.5 parts by weight of TD-2090 (provided by Japanese DIC Co., Ltd., hydroxy equivalent being 105 Wed) as the novolac curing agent to stir evenly, then add 30 parts by weight of phosphate aluminum (0 salt (provided by Clariant company, phosphorus content being 23%) as the flame retardant, then add 0.075 parts by weight of DMAP as the curing accelerator, then add methylbenzene as a solvent into the vessel, and continue to stir evenly, thereby obtaining a glue solution. Dip fiberglass cloth (type being 2116, thickness being 0.08 mm) in the above mentioned glue solution, control the fiberglass cloth to get an appropriate thickness, and then dry the fiberglass cloth by heat to remove the solvent, thereby obtaining prepregs. Overlay a plurality of the prepared prepregs with each other, respectively clad a piece of copper foil to the two sides of the prepregs overlaid with each other, and then cure the prepregs in hot press at a curing temperature of 150-250° C., a curing pressure of 25-60 Kg/cm² and a curing time of 90 minutes, thereby obtaining a copper clad laminate.

### Comparison Example 4

Set a vessel, add 100 parts by weight of biphenyl type novolac epoxy resin NC-3000H (provided by Nippon Kayaku Co., Ltd., EEW being 288 g/eq) into the vessel, then add 77.5 parts by solid weight of HPC-8000-65T (provided by Japanese DIC Co., Ltd., solid content being 65%) as the active ester curing agent to stir evenly, then add 53.1 parts by weight of phosphate ester PX-200 (provided by DAIHACHI CHEMICAL INDUSTRY CO., LTD., phosphorus content being 9%) as the flame retardant, then add 0.075 parts by weight of DMAP as the curing accelerator, then add methylbenzene as a solvent into the vessel, and continue to stir evenly, thereby obtaining a glue solution. Dip fiberglass cloth (type being 2116, thickness being 0.08 mm) in the above mentioned glue solution, control the fiberglass cloth to get an appropriate thickness, and then dry the fiberglass cloth by heat to remove the solvent, thereby obtaining prepregs. Overlay a plurality of the prepared prepregs with each other, respectively clad a piece of copper foil to the two sides of the prepregs overlaid with each other, and then cure the prepregs in hot press at a curing temperature of 150-250° C., a curing pressure of 25-60 Kg/cm² and a curing time of 90 minutes, thereby obtaining a copper clad laminate.

TABLE 1
the physical property data of the embodiments and the comparison examples

| performance | Embodi- | Embodi- | Embodi- | Embodi- | Embodi- | Embodi- |
|---|---|---|---|---|---|---|
| index | ment 1 | ment 2 | ment 3 | ment 4 | ment 5 | ment 6 |
| Tg(DMA)/° C. | 170 | 172 | 165 | 175 | 160 | 165 |
| Dk(5 G) | 3.8 | 3.8 | 3.8 | 3.7 | 3.9 | 3.9 |
| Df(5 G) | 0.0065 | 0.007 | 0.007 | 0.0085 | 0.0075 | 0.007 |
| hydroscopic | 0.12 | 0.13 | 0.13 | 0.13 | 0.12 | 0.14 |
| property, % | | | | | | |
| resistance to | 3/3 | 3/3 | 3/3 | 3/3 | 3/3 | 2/3 |
| humidity and | | | | | | |
| heat | | | | | | |
| flame | V-0 | V-0 | V-0 | V-0 | V-0 | V-0 |
| retardance | | | | | | |

TABLE 2
the physical property data of the embodiments and the comparison examples (to continue)

| performance | Embodi- | Embodi- | Comparison | Comparison | Comparison | Comparison |
|---|---|---|---|---|---|---|
| index | ment 7 | ment 8 | example 1 | example 2 | example 3 | example 4 |
| Tg(DMA)/° C. | 185 | 180 | 170 | 165 | 145 | 120 |
| Dk(5 G) | 3.85 | 3.85 | 3.9 | 3.9 | 3.9 | 3.95 |
| Df(5 G) | 0.0075 | 0.0075 | 0.013 | 0.0135 | 0.018 | 0.009 |
| hydroscopic | 0.12 | 0.13 | 0.15 | 0.18 | 0.21 | 0.25 |
| property, % | | | | | | |
| resistance to | 3/3 | 3/3 | 3/3 | 3/3 | 3/3 | 1/3 |
| humidity and | | | | | | |
| heat | | | | | | |
| flame | V-0 | V-0 | V-0 | V-0 | V-0 | V-0 |
| retardance | | | | | | |

As shown in the physical property data of Table 1 and Table 2, the comparison examples 1-2 adopt phenol novolac type epoxy resin and active ester to be cured, and comparing with the embodiments 1-8, the dielectric loss tangent is high; the epoxy resin with the same structure in the comparison example 3 adopts novolac to be cured with, but, the dielectric properties of the cured products are poor; phosphorus-containing flame retardant is adopted in the comparison example 4, but the cured products have low glass transition temperature, at the same time, for the hydroscopic property of the flame to retardant itself is high, the cured products have comparatively poor resistance to humidity and heat.

In summary, comparing with an ordinary copper foil substrate, the copper clad laminate of the present invention has more excellent dielectric properties and higher glass transition temperature, at the same time, also has good resistance to humidity and heat, which is fit for the field of high frequency.

Although the present invention has been described in detail with above said preferred embodiments, but it is not to limit the scope of the invention. So, all the modifications and changes according to the characteristic and spirit of the present invention, are involved in the protected scope of the invention.

What is claimed is:

1. An epoxy resin composition comprising: (A) epoxy resin containing two or over two epoxy groups, (B) active ester curing agent, and (C) phosphate salt compound;
the structure formula of the component (A) epoxy resin containing two or over two epoxy groups is shown as follows: 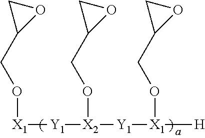
wherein, X₁ and X₂ are identical or different, representing 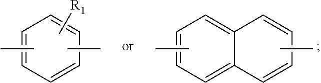
Y₁ representing 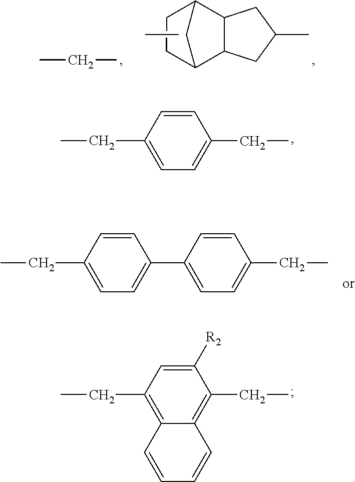
wherein, R₁ representing hydrogen atom, or alkyl with the number of carbon atoms being 1-10, and R₂ representing hydrogen atom, or alkyl with the number of carbon atoms being 1-10; a representing an integer of 1-30.

2. The epoxy resin composition of claim 1, wherein taking the usage amount of the component (A) epoxy resin containing two or over two epoxy groups as 100 parts by weight, the usage amount of the component (B) active ester curing agent is calculated according to the equivalent ratio of epoxy equivalent weight to active ester equivalent eight, and the equivalent ratio ranges from 0.85 to 1.2.

3. The epoxy resin composition of claim 2, wherein taking the total amount of the component (A), the component (B) and the component (C) as 100 parts by weight, the usage amount of the component (C) phosphate salt compound is 5-20 parts by weight.

4. The epoxy resin composition of claim 1, wherein the component (C) phosphate salt compound is prepared by metal ion reacting with a phosphate via substitution reaction, and the structure formula of the phosphate salt compound is shown as follows: 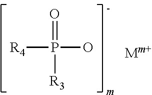
wherein, m represents 2 or 3; R₃ and R₄ represent alkyl with the number of carbon atoms being 1-6, or aryl; M represents metal atom that is one selected from calcium, magnesium, aluminum, arsenic, zinc, and iron.

5. The epoxy resin composition of claim 1, wherein the component (B) active ester curing agent is obtained from the reaction of a phenol compound containing aliphatic hydrocarbon structure as connection structure, together with bifunctional carboxylic acid aromatic compound or acid halide, and a monohydroxy compound; the usage amount of the bifunctional carboxylic acid aromatic compound or acid halide is 1 mol, the usage amount of the phenol compound containing aliphatic hydrocarbon structure as connection structure is 0.05-0.75 mol, and the usage amount of the monohydroxy compound is 0.25-0.95 mol.

6. The epoxy resin composition of claim 1, wherein the structure formula of the component (B) active ester curing agent is shown as follows: 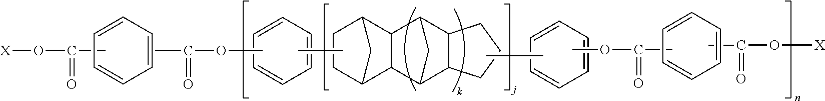
wherein, X represents benzene ring or naphthalene ring, represents 0 or 1, k represents 0 or 1, and n ranges from 0.25 to 2.5.

7. The epoxy resin composition of claim 1, wherein the epoxy resin composition also comprises curing accelerator, and the curing accelerator is one or a mixture of more selected from the group consisting of imidazole compounds, derivatives of imidazole compounds, piperidine compounds, Lewis acids, and triphenyl phosphine.

8. The epoxy resin composition of claim 1, wherein the epoxy resin composition also comprises filler, which is organic filler or inorganic filler; taking the total amount of the component (A), the component (B) and the component (C) as 100 parts by weight, the usage amount of the filler is 5-500 parts by weight; the inorganic filler is one or more selected from the group consisting of natural silica, fused silica, spherical silica, hollow silica, glass powder, aluminum nitride, boron nitride, silicon carbide, aluminum hydroxide, titanium dioxide, strontium titanate, barium titanate, alumina, barium sulfate, talcum powder, calcium silicate, calcium carbonate, and mica; the organic filler is one or more selected from polytetrafluoroethylene powder, polyphenylene sulfide powder, and poly(ether sulfones) powder.

9. A prepreg made from the epoxy resin composition of claim 1, wherein the prepreg comprises a reinforcing material, and the epoxy resin composition that adheres to the reinforcing material after the reinforcing material is dipped in the epoxy resin composition and then is dried.

10. A copper clad laminate made from the prepreg of claim 9, wherein the copper clad laminate comprises a plurality of laminated prepregs and copper foil cladded to one side or two sides of the laminated prepregs.
